(19) United States
(12) Patent Application Publication
(10) Pub. No.: US 2015/0171274 A1
(43) Pub. Date: Jun. 18, 2015

(54) LED STRUCTURE

(71) Applicant: Industrial Technology Research Institute, Hsinchu (TW)

(72) Inventors: Yih-Der GUO, Hsinchu City (TW); Yu-Hsiang CHANG, Zhudong Township (TW); Kun-Fong LIN, Hsinchu City (TW)

(73) Assignee: Industrial Technology Research Institute, Hsinchu (TW)

(21) Appl. No.: 14/109,174

(22) Filed: Dec. 17, 2013

(51) Int. Cl. H01L 33/32; H01L 33/40

(52) U.S. Cl. CPC H01L 33/32; H01L 33/40

(57) ABSTRACT

The present disclosure provides a LED structure which comprises an epitaxial layer, a current dispatching layer, a first electrode layer, and a second electrode layer. The epitaxial layer comprises sequentially disposed a high resistance buffer layer, a first GaN layer, an active layer, and a second GaN layer. A plurality of recesses are formed on a first surface of the epitaxial layer, each of the recesses has an opening on the first surface, penetrates the high resistance buffer layer, and contacts the first GaN layer. The current dispatching layer is disposed on the first surface of the epitaxial layer, and is disposed into the recesses for contacting the first GaN layer. The first electrode layer is disposed on the current dispatching layer, and the second electrode layer is disposed on a second surface of the epitaxial layer.

### BACKGROUND

1. Technical Field

The present disclosure relates to a LED structure.

2. Related Art

With the continuing development of technology, light-emitting diodes (LEDs) have been widely used in illumination devices due to their high brightness and long life-span. In general, the epitaxial layer of commercial LED is typically grown on wafers of sapphire (sapphire substrate). Because the sapphire wafers are undesirably expensive, the silicon wafers (silicon substrates) are nowadays applied for the LED industry with the advantage of relatively inexpensive cost as compared to the sapphire substrates.

However, there are many problems with growing high quality GaN layers on silicon substrates, for example, the lattice constant of silicon is substantially different from the lattice constant of GaN. Besides, the silicon substrate and the GaN layer may have different coefficients of thermal expansion, so that non-uniform stress may cause cracking and other problems. In general, a high resistance buffer layer is commonly used to be disposed between the GaN layer and the silicon substrate, so that the GaN layer can be grown on the silicon substrate. In practice, the traditional high resistance buffer layer greatly increase the impedance between the LED electrodes that may cause problems such as, for example, non-uniform current distribution, high operating voltage, and low illumination efficiency.

### SUMMARY

According to one aspect of the present disclosure, a LED structure comprises an epitaxial layer, a current dispatching layer, a first electrode layer, and a second electrode layer. The epitaxial layer comprises sequentially disposed a high resistance buffer layer, a first GaN layer, an active layer, and a second GaN layer. A plurality of recesses are formed on a first surface of the epitaxial layer, each of the recesses has an opening on the first surface, penetrates the high resistance buffer layer, and contacts the first GaN layer. The current dispatching layer is disposed on the first surface of the epitaxial layer, and is disposed into the recesses for contacting the first GaN layer. The first electrode layer is disposed on the current dispatching layer, and the second electrode layer is disposed on a second surface of the epitaxial layer.

### BRIEF DESCRIPTION OF THE DRAWINGS

The present disclosure can be more fully understood by reading the following detailed description of the embodiment, with reference made to the accompanying drawings as follows:

FIG. 1 is a perspective view of a LED structure according to an embodiment of the present disclosure.

FIG. 2 is a cross-sectional view of the LED structure according to an embodiment of the present disclosure.

FIG. 3 is a circuit diagram of the LED structure according to an embodiment of the present disclosure.

FIG. 4 is a top view of the LED structure according to an embodiment of the present disclosure.

FIG. 5a˜5f are a top view of the recesses according to an embodiment of the present disclosure.

### DETAILED DESCRIPTION

The detailed features and advantages of the disclosure are described below in great detail through the following embodiments, the content of which is sufficient for those of ordinary skill in the art to understand the technical content of the disclosure and to implement the disclosure accordingly. Based upon the content of the specification, the claims, and the drawings, those of ordinary skill in the art can easily understand the relevant objectives and advantages of the disclosure.

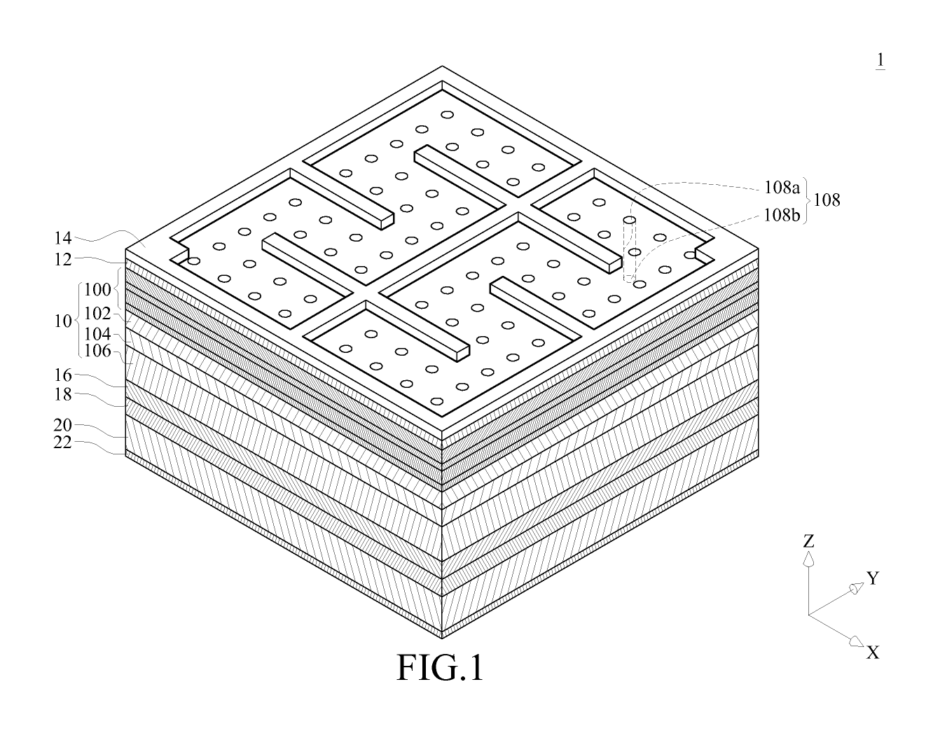

Please referred to FIG. 1, FIG. 1 is a perspective view of a LED structure according to an embodiment of the present disclosure. As shown in FIG. 1, the LED structure 1 has an epitaxial layer 10, a current dispatching layer 12, a first electrode layer 14, a second electrode layer 16, an adhesive layer 18, a substrate 20, and a bottom metal layer 22. The epitaxial layer 10 is disposed between the current dispatching layer 12 and the second electrode layer 16. The first electrode layer 14 is disposed on the current dispatching layer 12. The adhesive layer 18 is disposed between the second electrode layer 16 and the substrate 20, and the bottom metal layer 22 is attached to the other side of the substrate 20 as the bottom of the LED structure 1.

The epitaxial layer 10 is a multi-layers structure, and the epitaxial layer 10 at least has a high resistance buffer layer 100, a first GaN layer 102, an active layer 104, and a second GaN layer 106. The high resistance buffer layer 100, the first GaN layer 102, the active layer 104, and the second GaN layer 106 are stacked sequentially. In practice, the first GaN layer 102 can be a high quality n-GaN layer, the active layer 104 can be a multiple quantum well (MQW) active layer, and the second GaN layer 106 can be a high quality p-GaN layer.

To be noted, the epitaxial layer 10 is originally grown on a silicon substrate (not shown, already removed in FIG. 1), because the lattice constant of the silicon substrate is different from the lattice constant of the first GaN layer 102, and because the silicon substrate and the first GaN layer 102 have different thermal expansion rate, the high resistance buffer layer 100 is required. In an embodiment of the present disclosure, the high resistance buffer layer 100 is also a multi-layers structure to match the lattice constant and thermal expansion rate of both of the silicon substrate and the first GaN layer 102.

In practice, the high resistance buffer layer 100, the first GaN (n-GaN) layer 102, the active (MQW) layer 104, and the second GaN (p-GaN) layer 106 are sequentially disposed on the silicon substrate in the first place. And then, the second electrode layer 16, the adhesive layer 18, the substrate 20, and the bottom metal layer 22 are sequentially disposed on the second GaN (p-GaN) layer 106. After the bottom metal layer 22 is formed, the silicon substrate can be removed, for example, by chemicals, so that the first surface of the epitaxial layer 10 can be exposed.

Moreover, a plurality of recesses 108 are formed on the first surface of the epitaxial layer 10, and each of the recesses 108 has an opening on the first surface. The recesses 108 penetrate though the high resistance buffer layer 100, and contact the first GaN layer 102. The recesses 108 are non-through holes formed on the epitaxial layer 10, but could be considered as through holes in view of the high resistance buffer layer 100. The diameter of each recess 108 may be 3˜5 μm (e.g. 4 μm) or 1˜20 μm.

And then, the current dispatching layer 12 can be disposed (could be pasted or coated) on the first surface of the epitaxial layer 10, and can be filled into the recesses 108. In practice, the current dispatching layer 12 could be only a thin film covering the side wall 108a and the bottom surface 108b of the recesses 108. The current dispatching layer 12 is made of conductive materials such as indium tin oxide (ITO), and the current dispatching layer 12 is configured to provide a current path directly from the first GaN layer 102 to the first surface of the epitaxial layer 10. Thus, the current path bypasses the high resistance buffer layer 100 to provide a shortcut without huge resistance. In an embodiment of the present disclosure, the current dispatching layer 12 which covers the side wall 108a of the recesses 108 can be considered as a vertical transparent conductive layer, and the current dispatching layer covers the bottom surface 108b of the recesses 108 can be considered as a horizontal ohmic contact layer.

After the current dispatching layer 12 is disposed, the first electrode layer 14 can be disposed on the current dispatching layer 12. In practice, the recesses 108 do not filled up with the current dispatching layer 12, and the first electrode layer 14 can also be filled into a part of the recesses 108. To be noted, the first electrode layer 14 may not fully cover the current dispatching layer 12. In practice, the first electrode layer 14 is made of metal material, which may block the emitted light, thus the first electrode layer 14 may only be disposed in specific pattern.

Besides, the high resistance buffer layer 100 could be roughened to increase the light illumination efficiency after the silicon substrate is removed, and the current dispatching layer 12 disposed on the roughened high resistance buffer layer 100 may or may not have a flat surface. The present disclosure does not limit the means to roughen the high resistance buffer layer 100 or to form the recesses 108 on the first surface of the epitaxial layer 10, those skilled in the art may select proper means.

In an embodiment of the present disclosure, the first surface of the roughened high resistance buffer layer 100 may smaller than 3 μm roughness (or gap depth) or have 2˜4 μm, and the roughened high resistance buffer layer 100 could be considered as a tiny prism array to increase the light illumination efficiency.

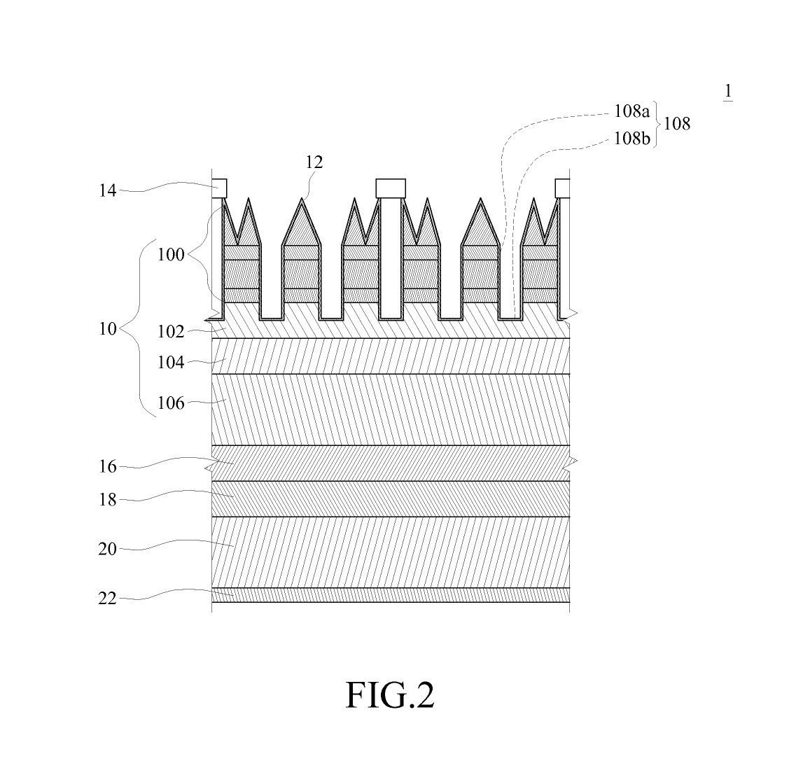

Please referred to FIG. 2, FIG. 2 is a cross-sectional view of the LED structure according to an embodiment of the present disclosure. As shown in FIG. 2, the depth of each of the recesses 108 can be clearly shown. In this case, a portion of the side wall 108a and the whole bottom surface 108b contact the first GaN layer 102, but the present disclosure does not limit how deep the recess 108 is. In practice, a portion of the side wall 108a of the recesses 108 contacts the first GaN layer 102 may be helpful to increase the conductivity between the first GaN layer 102 and the current dispatching layer 12. However, the first GaN layer 102 only contacts the bottom surface 108b of the recess 108 that the first GaN layer 102 may still be able to be coupled to the current dispatching layer 12.

As shown in FIG. 2, the first electrode layer 14 can also be filled into some specific recesses 108, and the pillar-shaped first electrode layer 14 could be surrounded by the current dispatching layer 12 within the recess 108. That is, the first electrode layer 14 may fully contact the current dispatching layer 12 which is coupled to the first GaN layer 102, and the parallel recesses 108 covered by the current dispatching layer 12 contact the first GaN layer 102 so that the power carried by the first electrode layer 14 can be spread to the first GaN layer 102 through the recesses 108.

To be noted, where the first GaN layer 102 contacts the bottom surface 108b of the recess 108 has a n-type doping density no less than 1×10¹⁸ cm⁻³. Therefore, the proper n-type doping density can provide good current conductivity that the current dispatching layer 12 and the first GaN layer 102 may form the current path mentioned above.

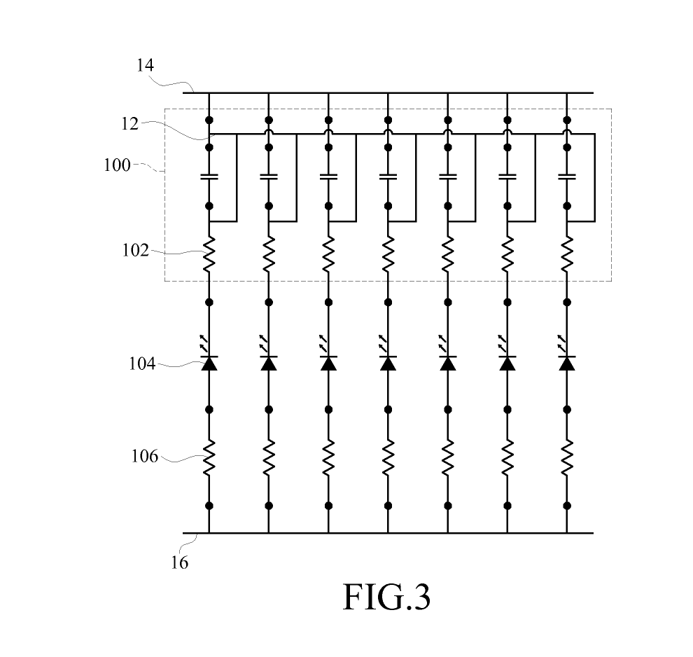

Please referred to FIG. 2 and FIG. 3, FIG. 3 is a circuit diagram of the LED structure according to an embodiment of the present disclosure. As shown in figures, the first electrode layer 14 and the second electrode layer 16 are configured to receive power, and the first GaN layer 102, the active layer 104, and the second GaN layer 106 are configured to convert electrical energy into light. The recesses 108 can be considered as several parallel shortcuts which directly connect the current dispatching layer 12 (equivalent to the first electrode layer 14) to the first GaN layer 102. That is, the current dispatching layer 12 within the recesses 108 can provide additional current paths coupled the first electrode layer 14 to the first GaN layer 102.

Therefore, the high resistance buffer layer 100 is bypassed, the present disclosure can reduce the equivalent impedance between LED electrodes to enhance illumination efficiency. Besides, the current dispatching layer 12 can also uniformize the current distribution within the active layer 104, because the number of the current paths which provide power to the first GaN layer 102 is greatly increased.

In general, increasing the number of the electrodes may be able to increase the uniformity of the current distribution, but the electrodes may block the light emitted from the active layer 104. The present disclosure utilizes the substantially transparent current dispatching layer 12 which does not block the light. Thus, the present disclosure does not need to increase the number of the electrodes (or covering area of the first electrode layer 14), and provides a solution to increase the uniformity of the current distribution.

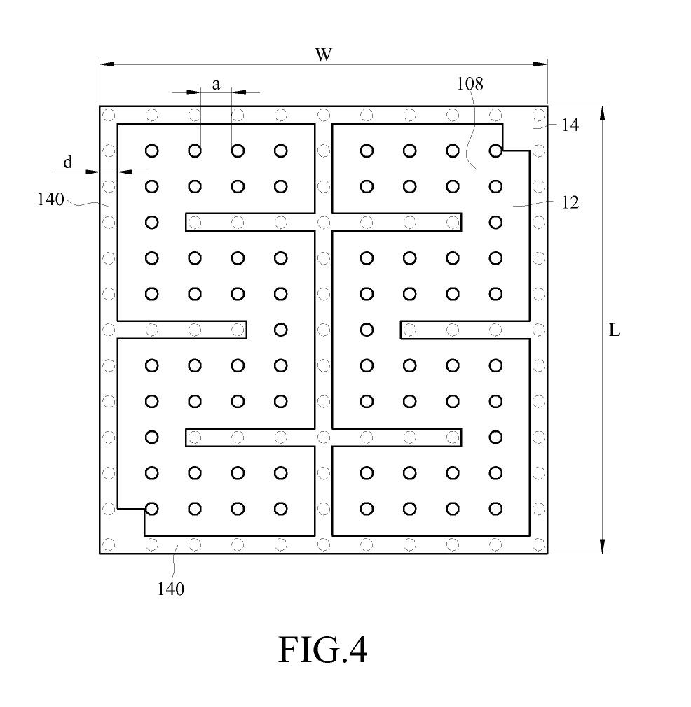

Please referred to FIG. 4, FIG. 4 is a top view of the LED structure according to an embodiment of the present disclosure. As shown in FIG. 4, the first electrode layer 14 is disposed on the current dispatching layer 12. The first electrode layer 14 is disposed in specific pattern, for example, there are several electrode bars 140 in the specific pattern. And, the recesses 108 are also disposed in an array-like pattern. In practice, the size of the opening of the recess 108 can not be larger than the width (d) of the electrode bar 140 of the first electrode layer 14. For example, the size of the opening of the recess 108 equals to 4 μm, and the width (d) of the electrode bar 140 equals to 10 μm. And, the minimum distance (a) between two of the adjacent openings may be 3˜5 μm (e.g. 4 μm) or 1˜20 μm. Besides, the area of the openings of the recesses 108 is no greater than 20% of the area of the whole LED structure 1 (W×L) from the top-view. The present disclosure does not limit the specific pattern shown in FIG. 4, those skilled in the art may select another proper pattern as a predetermined pattern.

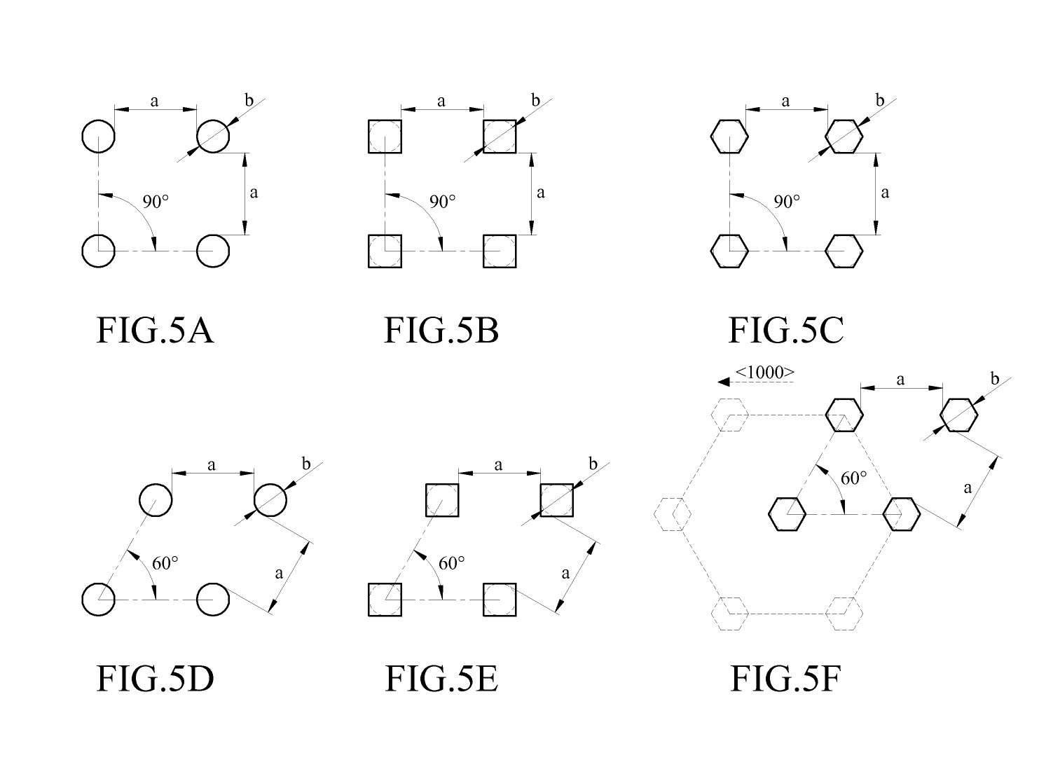

Please referred to FIG. 5a˜5f, FIG. 5a˜5f are a top view of the recesses according to an embodiment of the present disclosure. As shown in FIG. 5a˜5c, the recesses (108) are arranged in rectangular array, the difference between FIG. 5a˜5c shall be the shape of the recesses (especially the shape of the openings of the recesses). FIG. 5a discloses the recesses which have circular shape, FIG. 5b discloses the recesses which have rectangular shape, and FIG. 5a discloses the recesses which have hexagonal shape. To be noted, the minimum distance (a) between the adjacent recesses and the diameter (b) of each recess are not limited in this embodiment, the diameter (b) of the recess shall be the diameter of inscribed circle of each shape of the recess. As mentioned before, the minimum distance (a) between two of the adjacent openings may be 1˜20 μm, the diameter (b) of each recess may also be 1˜20 μm. In this embodiment, the minimum distance (a) and the diameter (b) are both equal to 4 μm.

As shown in FIG. 5d˜5f, the recesses (108) are arranged in hexagonal array, the difference between FIG. 5d˜5f shall be the shape of the recesses (especially the shape of the openings of the recesses). FIG. 5d discloses the recesses which have circular shape, FIG. 5e discloses the recesses which have rectangular shape, and FIG. 5f discloses the recesses which have hexagonal shape. In practice, the recesses are arranged along the crystal lattice orientation of gallium nitride, for example, the crystal lattice orientation of gallium nitride could be <1000>.

The embodiments depicted above and the appended drawings are exemplary and are not intended to be exhaustive or to limit the scope of the present disclosure to the precise forms disclosed. Many modifications and variations are possible in view of the above teachings.

What is claimed is:

1. A LED structure, comprising:
an epitaxial layer, comprising sequentially disposed a high resistance buffer layer, a first GaN layer, an active layer, and a second GaN layer, wherein a plurality of recesses are formed on a first surface of the epitaxial layer, each of the recesses has an opening on the first surface, penetrates the high resistance buffer layer, and contacts the first GaN layer;
a current dispatching layer disposed on the first surface of the epitaxial layer, and being disposed into the recesses for contacting the first GaN layer;
a first electrode layer disposed on the current dispatching layer; and
a second electrode layer disposed on a second surface of the epitaxial layer.

2. The LED structure of claim 1, wherein the first surface of the epitaxial layer is roughened before the current dispatching layer is disposed thereon.

3. The LED structure of claim 1, wherein each of the recesses has a side wall and a bottom surface, at least the bottom surface of the recess contacts the first GaN layer.

4. The LED structure of claim 3, wherein the bottom surface and a part of the side wall contact the first GaN layer.

5. The LED structure of claim 3, wherein where the first GaN layer contacts the bottom surface of the recess has a n-type doping density no less than 1×10¹⁸ cm⁻³.

6. The LED structure of claim 3, wherein the current dispatching layer covers the side wall and the bottom surface of the recesses.

7. The LED structure of claim 6, wherein the current dispatching layer covering the side wall of the recesses is a transparent conductive layer, and the current dispatching layer covering the bottom surface of the recesses is an ohmic contact layer.

8. The LED structure of claim 6, wherein the current dispatching layer is made of indium tin oxide.

9. The LED structure of claim 3, wherein the first electrode layer is formed in a predetermined pattern covering a portion of the current dispatching layer, and the first electrode layer is filled into a part of the recesses.

10. The LED structure of claim 9, wherein the opening of each recess is circular shape, rectangular shape, or hexagonal shape.

11. The LED structure of claim 1, wherein the minimum distance between two of the adjacent openings is 1˜20 μm.

12. The LED structure of claim 11, wherein the diameter of the recess is 1˜20 μm.

13. The LED structure of claim 12, wherein the area of the openings of the recesses is no greater than 20% of the area of the LED structure from the top-view.

14. The LED structure of claim 12, wherein the first electrode layer has a plurality of electrode bars, the electrode bars are electrically connected to each other, and the electrode bars are disposed on the current dispatching layer.

15. The LED structure of claim 14, wherein the width of the electrode bar is larger than the diameter of the recess.

16. The LED structure of claim 1, wherein the first GaN layer is a n-GaN layer.

17. The LED structure of claim 1, wherein the second GaN layer is a p-GaN layer.

18. The LED structure of claim 1, wherein the recesses are arranged along the crystal lattice orientation of gallium nitride.
